(19) United States
(12) Patent Application Publication
(10) Pub. No.: US 2013/0342610 A1
(43) Pub. Date: Dec. 26, 2013

(54) PIEZOELECTRIC ACTUATOR, INKJET HEAD ASSEMBLY AND METHOD OF MANUFACTURING THE SAME

(71) Applicants: Tae Kyung LEE, Suwon (KR); Pil Joong Kang, Suwon (KR); Jae Chang Lee, Suwon (KR); Hwa Sun Lee, Suwon (KR)

(72) Inventors: Tae Kyung LEE, Suwon (KR); Pil Joong Kang, Suwon (KR); Jae Chang Lee, Suwon (KR); Hwa Sun Lee, Suwon (KR)

(73) Assignee: SAMSUNG ELECTRO-MECHANICS CO., LTD., Suwon (KR)

(21) Appl. No.: 13/609,580

(22) Filed: Sep. 11, 2012

(30) Foreign Application Priority Data
Jun. 20, 2012 (KR) 10-2012-0066353

(51) Int. Cl. B41J 2/045; H01L 41/22; H01L 41/047

(52) U.S. Cl. 347/71; 310/331; 29/25.35

(57) ABSTRACT

There are provided a piezoelectric actuator, an inkjet head assembly, and a method of manufacturing the same. The piezoelectric actuator includes upper and lower electrodes providing a driving voltage; and a piezoelectric body provided between the upper and lower electrodes and providing driving force to ink within each of a plurality of pressure chambers provided in an inkjet head, wherein the piezoelectric body includes branch portions separately provided on an upper portion of each of the plurality of pressure chambers and a large area portion connected to one end of each of the plurality of branch portions and integrally formed, and a connective electrode pattern is provided on a portion of each of the upper electrodes corresponding to the large area portion.

### CROSS-REFERENCE TO RELATED APPLICATIONS

This application claims the priority of Korean Patent Application No. 10-2012-0066353 filed on Jun. 20, 2012, in the Korean Intellectual Property Office, the disclosure of which is incorporated herein by reference.

### BACKGROUND OF THE INVENTION

1. Field of the Invention

The present invention relates to a piezoelectric actuator, an inkjet head assembly, and a method of manufacturing the same.

2. Description of the Related Art

In general, an inkjet head is a structure in which ink is ejected in the form of droplets through a small nozzle by converting an electrical signal into physical force. Inkjet heads are classified into two types, depending on an ink ejection scheme adopted thereby. One type is a thermally driven type inkjet head in which ink is bubbled by using a heat source to eject the ink by the expansive power of bubbles, and the other type is a piezoelectric type inkjet head in which a piezoelectric body is used and ink is ejected by pressure applied thereto as the piezoelectric body is deformed.

In particular, recently, a piezoelectric type inkjet head has been used extensively in industrial inkjet printers. For example, a piezoelectric type inkjet head is used to jet ink generated by melting a metal such as gold, silver, and the like, to a flexible printed circuit board (FPCB) so as to directly form a circuit pattern thereon, or is used for industrial graphics, used to manufacture liquid crystal display (LCD) or an organic light emitting diode (OLED), or used in solar cells, and the like.

A piezoelectric type inkjet head has a structure in which a piezoelectric actuator is provided on an upper portion of an inkjet head plate having a pressure chamber to apply pressure to ink disposed therein. Thus, a driving electrode of a piezoelectric actuator is wired to supply a voltage thereto.

However, in general, in a piezoelectric actuator, a piezoelectric liquid is applied in the form of a paste to be solidified, thereby being used. Thus, when a piezoelectric body is formed to have a shape corresponding to the pressure chamber formed extendedly in a length direction, an upper portion thereof is formed to be rounded in a width direction, having a rounded shape, rather than a flat shape. Thus, a driving electrode formed on the upper portion of the piezoelectric body also has a rounded shape.

The actuator itself, although having a rounded shape, is not problematic, but since the driving electrode to be connected to a flexible printed circuit to supply power has a rounded shape, it may be difficult to perform soldering, or the like thereon, and although connected, it may be short-circuited, or the like, causing a defect.

Also, the driving electrode is coated overall in a length direction on an upper portion of the piezoelectric liquid, and here, in order to reduce material wastage, the driving electrode is coated as thinly as possible. In this case, a portion of the driving electrode connected to the flexible printed circuit is so thin that the coated driving electrode may be stripped in the case of wire bonding, generating a defect.

### SUMMARY OF THE INVENTION

An aspect of the present invention provides a piezoelectric actuator in which piezoelectric bodies are provided to correspond to respective pressure chambers and a driving electrode is formed to be flat so as to be accurately and firmly connected to a flexible printed circuit.

Another aspect of the present invention provides a piezoelectric actuator in which a driving electrode is not stripped even in a case of wire bonding.

According to an aspect of the present invention, there is provided a piezoelectric actuator including: upper and lower electrodes providing a driving voltage; and a piezoelectric body provided between the upper and lower electrodes and providing driving force to ink within each of a plurality of pressure chambers provided in an inkjet head, wherein the piezoelectric body includes branch portions separately provided on an upper portion of each of the plurality of pressure chambers and a large area portion connected to one end of each of the plurality of branch portions and integrally formed, and a connective electrode pattern is provided on a portion of each of the upper electrodes corresponding to the large area portion.

The upper electrodes may be separately provided to extend from the branch portions to the large area portion.

The upper electrodes may include connection portions provided on portions thereof positioned on an upper portion of the large area portion, and having a width greater than those of other portions for an electrical wiring to apply a voltage to the upper electrodes, and the connective electrode pattern may be provided on each of the connection portions.

The connection portions may be provided in different positions in a length direction on a plurality of the upper electrodes.

The connection portions may be disposed in zigzags on a plurality of the upper electrodes.

According to another aspect of the present invention, there is provided an inkjet head assembly including: a piezoelectric actuator formed to correspond to a plurality of pressure chambers within the inkjet head plate and providing driving force to eject ink from the pressure chambers to nozzles, wherein the piezoelectric actuator includes: upper and lower electrodes providing a driving voltage; and a piezoelectric body formed between the upper and lower electrodes by solidifying a piezoelectric liquid and providing driving force to ink within each of the plurality of pressure chambers provided in an inkjet head, wherein the piezoelectric body includes branch portions separately provided on an upper portion of each of the plurality of pressure chambers and a large area portion connected to one end of each of the plurality of branch portions and integrally formed, and a connective electrode patterns is provided on an upper portion of each of the upper electrodes provided in the large area portion.

The upper electrodes may be separately formed to extend from the branch portions to the large area portion.

The upper electrodes may include connection portions provided on portions thereof positioned on an upper portion of the large area portion, and having a width greater than those of other portions for an electrical wiring to apply a voltage to the upper electrodes, and the connective electrode pattern may be provided on each of the connection portions.

The inkjet head assembly may further include: a package unit stacked on the inkjet head plate and having a flow path formed therein and allowing the ink introduced from an outside to be transferred to an inlet of the inkjet head plate; and an electrical connection unit filled in a via formed to penetrate the package unit and electrically connected to the connective electrode pattern of the piezoelectric actuator.

The inkjet head assembly may further include: a connection member electrically connecting the electrical connection unit and the connective electrode pattern to each other.

The connection member may be formed of a solder ball.

According to another aspect of the present invention, there is provided a method of manufacturing an inkjet head assembly, the method including: forming an ink flow path including a plurality of pressure chambers in an inkjet head plate; forming a lower electrode on an upper portion of the inkjet head plate; forming a piezoelectric body through an application of a piezoelectric liquid in a paste state and a solidification thereof such that the piezoelectric body includes a plurality of branch portions respectively provided to correspond to the plurality of pressure chambers and a large area portion connected to one end of each of the plurality of branch portions and integrally formed, on an upper portion of the lower electrode; separately forming upper electrodes to extend from the branch portions to the large area portion on an upper portion of the piezoelectric body; and forming a connective electrode pattern on an upper portion of each of the upper electrodes provided on the large area portion.

In the forming of the upper electrodes, connection portions having a width greater than those of other portions may be provided on portions of the upper electrodes positioned on an upper portion of the large area portion, for an electrical wiring to apply a voltage to the upper electrodes, and the connective electrode pattern may be provided on each of the connection portions.

The connection portions may be provided in different positions in a length direction on a plurality of the upper electrodes.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cutaway perspective view illustrating an inkjet head assembly according to an embodiment of the present invention;

FIG. 2 is a schematic cross-sectional view illustrating the inkjet head assembly according to an embodiment of the present invention;

FIG. 3 is a schematic plan view illustrating the inkjet head assembly according to an embodiment of the present invention;

FIG. 4 is a schematic perspective view illustrating a mounting structure of the inkjet head assembly according to an embodiment of the present invention;

FIG. 5 is a schematic cutaway perspective view illustrating an inkjet head assembly according to another embodiment of the present invention;

FIG. 6 is a schematic cross-sectional view illustrating the inkjet head assembly according to another embodiment of the present invention;

FIG. 7 is a schematic plan view illustrating the inkjet head assembly according to another embodiment of the present invention;

FIG. 8 is a schematic plan view illustrating an ink flow path of a package unit of the inkjet head assembly according to another embodiment of the present invention;

FIG. 9 is a cross-sectional view showing the ink flow path of the inkjet head assembly according to another embodiment of the present invention; and

FIG. 10 is a schematic perspective view illustrating a mounting structure of the inkjet head assembly according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

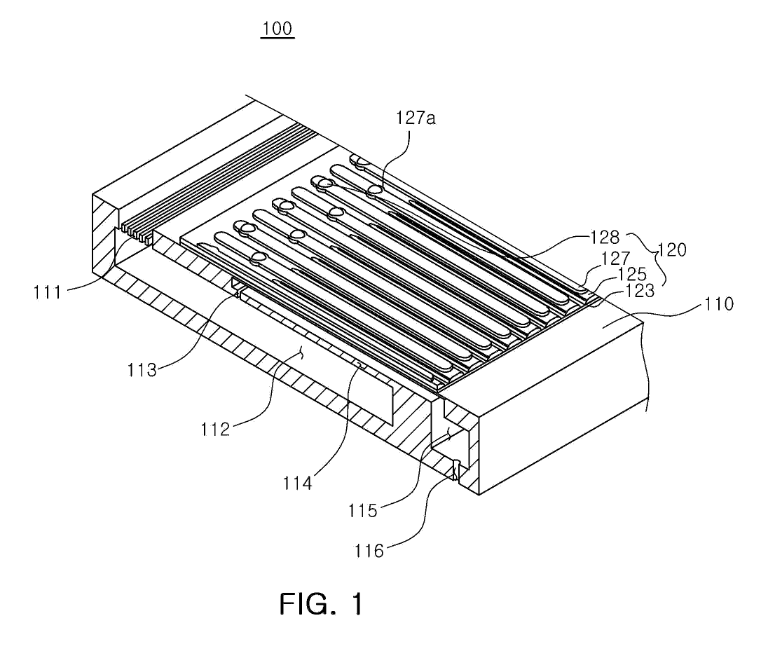

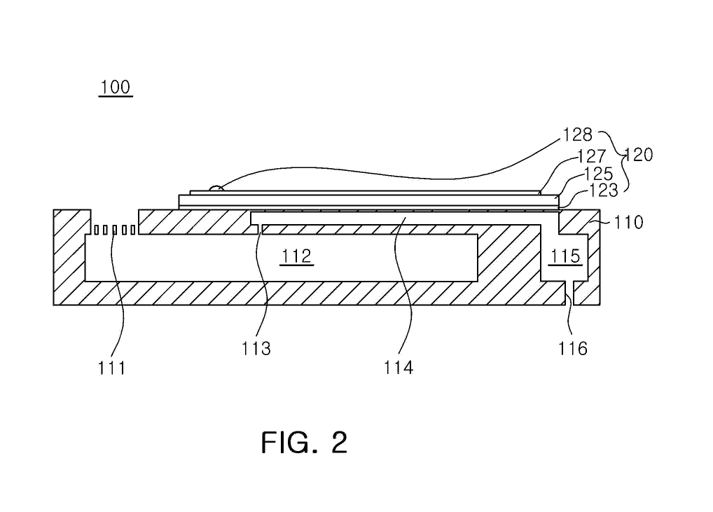

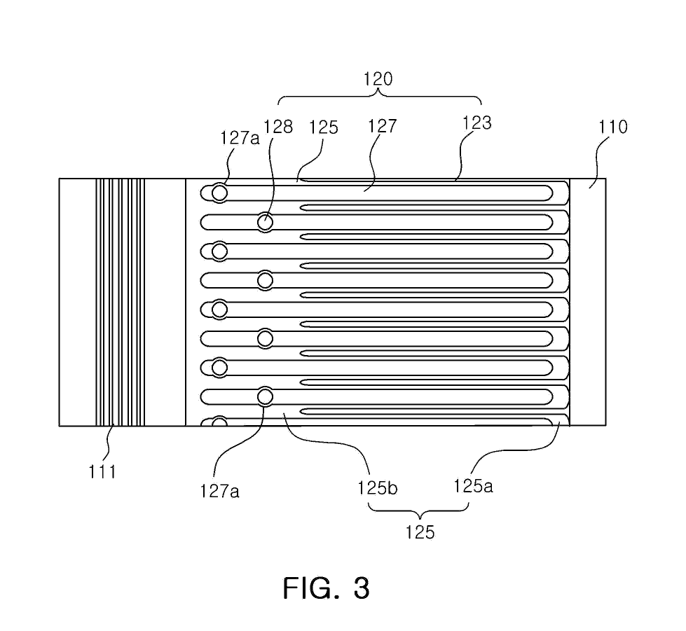

FIG. 1 is a schematic cutaway perspective view illustrating an inkjet head assembly according to an embodiment of the present invention; FIG. 2 is a schematic cross-sectional view illustrating the inkjet head assembly according to an embodiment of the present invention; and FIG. 3 is a schematic plan view illustrating the inkjet head assembly according to an embodiment of the present invention.

Referring to FIGS. 1 through 3, an inkjet head assembly 100 according to an embodiment of the present invention may include an inkjet head plate 110 in which an ink flow path is formed and a piezoelectric actuator 120 providing driving force for ejecting ink to the inkjet head plate 110.

The inkjet head plate 110 may include an ink inlet 111 through which ink is introduced, a reservoir 112 storing the ink introduced through the ink inlet 111, a plurality of pressure chambers 114 provided below the position in which the piezoelectric actuator 120 is mounted, and a plurality of nozzles 116 ejecting ink. A plurality of restrictors 113 may be formed between the reservoir 112 and the pressure chambers 114 in order to restrain ink in the pressure chambers 114 from flowing backward to the reservoir 112 when the ink is ejected. Also, the pressure chambers 114 and the nozzles 116 may be connected by a plurality of dampers 115 alleviating ink pumping from the pressure chambers 114 to the nozzles 116.

The inkjet head plate 110 may be formed by appropriately forming the components constituting the g ink flow path on upper and lower substrates and bonding the upper and lower substrates according to a scheme such as silicon direct bonding (SDB), or the like. Here, the upper substrate may be a single crystalline silicon substrate or a silicon-on-insulator (SOI) substrate, and the lower substrate may be an SOI substrate. Also, without being limited thereto, the inkjet head plate 110 may configure an ink flow path by using a larger number of substrates, and may be implemented by a single substrate in some cases. The components forming the ink flow path are also merely illustrative, and ink flow paths having various configurations according to requirements and design specifications may be provided.

The piezoelectric actuator 120 is formed on an upper portion of the inkjet head plate 110 so as to correspond to the pressure chambers 114 of the inkjet head plate 110, and provides driving force for ejecting ink introduced into the pressure chambers 114 to the nozzles 116. For example, the piezoelectric actuator 120 may include a lower electrode 123 serving as a common electrode, a piezoelectric film (or a piezoelectric body) 125 deformed according to a voltage applied thereto, upper electrodes 127 serving as driving electrodes, and connective electrode patterns 128 provided on upper portions of the upper electrodes 127 to prevent the upper electrodes 127 from being stripped even in the case of wire bonding.

The lower electrode 123 may be formed across the entire surface of the inkjet head plate 110, and may be made of a single conductive metal material, but preferably, formed of two metal thin film layers including titanium (Ti) and platinum (Pt). The lower electrode 123 may also serve as a diffusion prevention layer preventing mutual diffusion between the piezoelectric film (or the piezoelectric body) 125 and the inkjet head plate 110, as well as serving as the common electrode. Namely, when a piezoelectric liquid made of a ceramic material is applied to an upper portion of the inkjet head plate 110 made of a silicon material, a portion of the piezoelectric ceramic material may diffused into the inkjet head plate 110 made of a silicon material, and in this case, the lower electrode 123 prevents the diffusion.

The piezoelectric film (or piezoelectric body) 125 may be formed on the lower electrode 123 and may be formed by solidifying a piezoelectric liquid in a paste state. The piezoelectric film 125 may include branch portions 125a individually provided on respective upper portions of the plurality of pressure chambers 114 and a large area portion 125b connected to one end of each of the plurality of branch regions 125a and integrally formed. Namely, a piezoelectric liquid in a paste state may be applied to the individual branch portions 125a on the upper portions of the pressure chambers 114. The piezoelectric liquid in a paste state may be applied to the portion other than the branch portions 125a to have a shape of an entirely connected large area and may be solidified, such that the piezoelectric film (or the piezoelectric body) 125 may be formed to have a substantially fork-shaped head, overall.

In a piezoelectric actuator according to the related art, a piezoelectric liquid is applied in the form of a paste and solidified to be used. Thus, when a piezoelectric body is formed to have a shape corresponding to a pressure chamber extended in a length direction, an upper portion thereof is formed to be rounded in a width direction and has a rounded shape, rather than a flat shape. Thus, the driving electrode formed on an upper portion of the piezoelectric body also has a rounded shape. Here, the actuator itself, though having a rounded shape, is not problematic, but since the driving electrode to be connected to a flexible printed circuit to supply power has a rounded shape, soldering or the like may not be facilitated. Even though the driving electrode may be connected to the circuit, it may short-circuited, or the like, causing a defect.

Thus, in the embodiment of the present invention, the piezoelectric film 125 is formed to have the large area portion 125b. Namely, even in the case that the piezoelectric liquid is applied in the form of a paste, since the piezoelectric liquid may be applied to a large area, an upper surface of the large area portion 125b is formed as a flat surface overall and solidified, even though edge portions of the large area portion 125b have a stepped rounded shape. Thus, unlike the piezoelectric body of the related art, formed to have a rounded shape, the piezoelectric body according to the embodiment of the present invention is formed to be flat, the flexible printed circuit may be reliably and firmly connected to the upper electrode 127 (i.e., the driving electrode) applied to the upper portion of the piezoelectric body.

The piezoelectric film 125 is made of a piezoelectric material, preferably, a lead zirconate titanate (PZT) ceramic material. Also, as described above, the piezoelectric film 125 may be formed through an application of a piezoelectric liquid in a paste state and a solidification thereof.

The upper electrode 127 may be formed on the piezoelectric film 125 and may be made of any one of materials such as platinum (Pt), gold (Au), silver (Ag), nickel (Ni), titanium (Ti), copper (Cu), and the like. The upper electrodes 127 may be separately provided to extend from the branch portion 125a to the large area portion 125b. Namely, the upper electrodes 127 may not be connected to each other and a plurality of upper electrodes corresponding to the number of the pressure chambers 112 are provided to serve as driving electrodes of the pressure chambers 112, respectively.

Here, the upper electrodes 127 may include connection portions 127a formed on portions thereof positioned on the upper portion of the large area portion 125b and having a width greater than those of other portions for electrical wiring to apply a voltage to the upper electrode 127. The connection portion 127a serves to accurately connect the upper electrode 127 and the flexible printed circuit 165 to each other. Namely, a portion of the upper electrode 127 connected to the flexible printed circuit 165 may have a larger connection area.

Also, the connection portions 127a may be provided in different positions in the length direction on the plurality of upper electrodes 127. Namely, by differentiating the positions of the connection portions 127a on the respective upper electrodes 127, the upper electrode 127 including the connection portion 127a having a large width may be prevented from being shorted with upper electrodes 127 adjacent thereto. In detail, the connection portions 127a may be disposed in zigzags on the plurality of upper electrodes 127.

The connective electrode pattern 128 may be provided on the upper portion of the upper electrode 127. The upper electrode 127 as the driving electrode may be applied in the length direction on the upper portion of the piezoelectric body 125. Thus, in order to reduce materials wastage, the upper electrode 127 is formed to be as thin as possible, and here, a portion of the upper electrode 127 connected to the flexible printed circuit and being relatively thin may be stripped in the case of wire bonding, causing a defect. Thus, the connective electrode pattern 128 is additionally provided on the upper portion of the upper electrode 127 to increase the thickness of the electrode applied to the upper portion of the piezoelectric body 125, thus preventing the upper electrode 127 from being stripped.

The connective electrode pattern 128 is provided on the portion connected to the flexible printed circuit, so the connective electrode pattern 128 may be provided on a portion corresponding to the large area portion 125b of the piezoelectric body 125.

Also, the connection portion 127a having a width greater than those of the other portions may be provided on a portion of the upper electrode 127 positioned on the upper portion of the large area portion 125b, for electrical wiring to apply a voltage to the upper electrode 127, and the connective electrode pattern 128 may be provided in the connection portion 127a.

Also, since the connective electrode pattern 128 substantially serves as the upper electrode, the connective electrode pattern 128 may be made of the same material as that of the upper electrode. Namely, the connective electrode pattern 128 may be made of any one of materials such as platinum (Pt), gold (Au), silver (Ag), nickel (Ni), titanium (Ti), copper (Cu), and the like. However, the present invention is not limited thereto and the connective electrode pattern 128 may be made of any material able to serve as an electrode, different from that of the upper electrode.

Also, when viewed from the plane, the connective electrode pattern 128 may have a circle having a certain diameter or may be extended in a length direction.

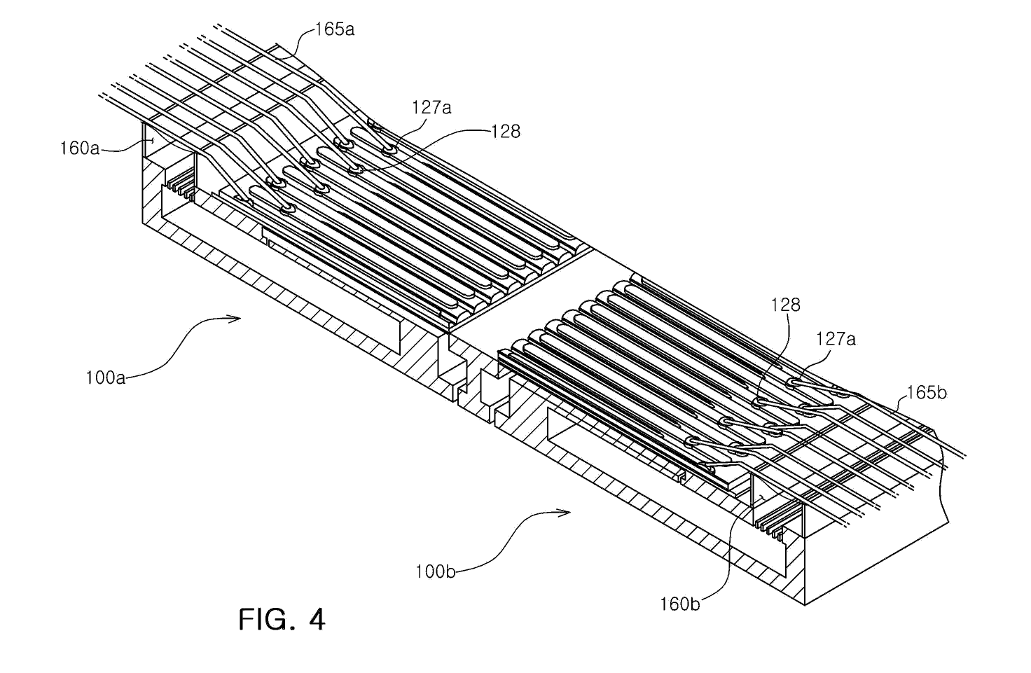

FIG. 4 is a schematic perspective view illustrating a mounting structure of the inkjet head assembly according to an embodiment of the present invention.

Referring to FIG. 4, a mounting structure of an inkjet head assembly according to an embodiment of the present invention includes first and second inkjet head assemblies 100a and 100b, disposed to be symmetrical with relation to one another, ink storage tanks 160a and 160b disposed at both end portions of the first and second inkjet head assemblies 100a and 100b, and flexible printed circuits 165a and 165b connected to upper electrodes of the first and second inkjet head assemblies 100a and 100b.

As described above, in the inkjet head assembly according to the embodiment of the present invention, the connection portions 127a may be provided on the upper electrodes 127, and the portion of the piezoelectric body 125 corresponding to the portions of the upper electrodes 127 to which the flexible printed circuits 165a and 165b are connected may be formed to be flat to allow the upper electrodes 127 provided thereon to be flat, thus facilitating the connection of the flexible printed circuits and the upper electrodes as well as accurately and firmly connecting the flexible printed circuits and the upper electrodes.

Also, the connective electrode patterns 128 may be additionally provided in the connection portions 127a of the upper electrodes 127 to thus prevent the upper electrodes from being stripped when the flexible printed circuits and the upper electrodes are connected.

Meanwhile, an inkjet head assembly 100′ according to another embodiment of the present invention only includes a single ink storage tank in order to reflect the trend of a reduction in size and weight in comparison with the inkjet head assembly according to the foregoing embodiment in which one ink storage tank is provided for each head assembly, basically requiring two ink storage tanks generally disposed to the left and right as described above.

The inkjet head assembly 100′, according to another embodiment of the present invention, further includes a package unit 130 to be described later, in addition to the configuration of the inkjet head plate 110 and the piezoelectric actuator 120. Thus, the package unit 130 will be described hereinafter.

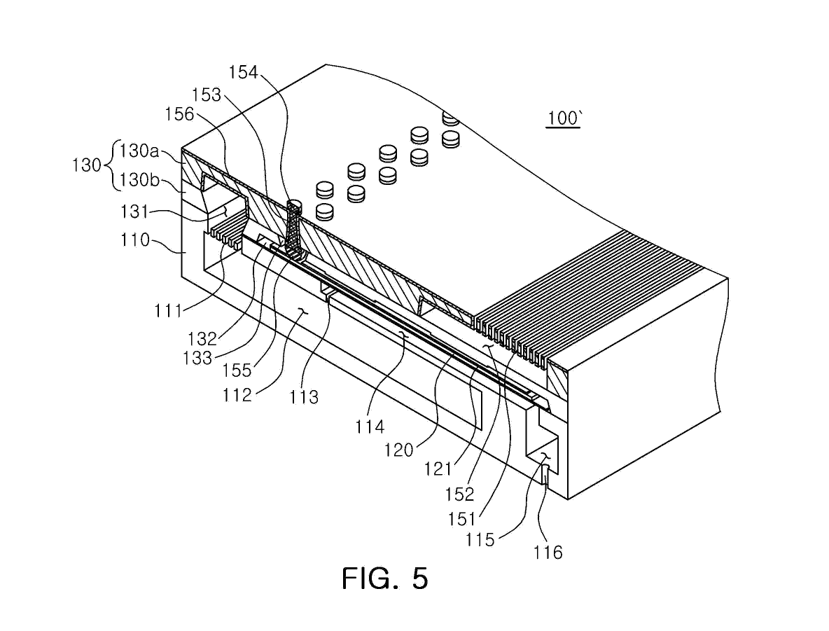

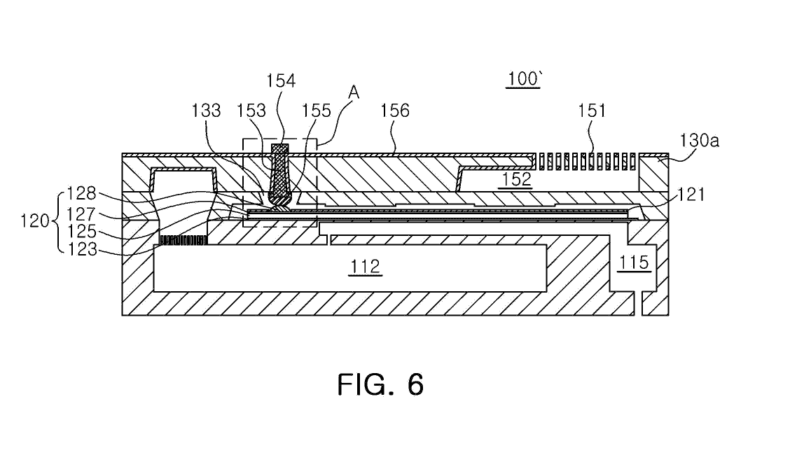

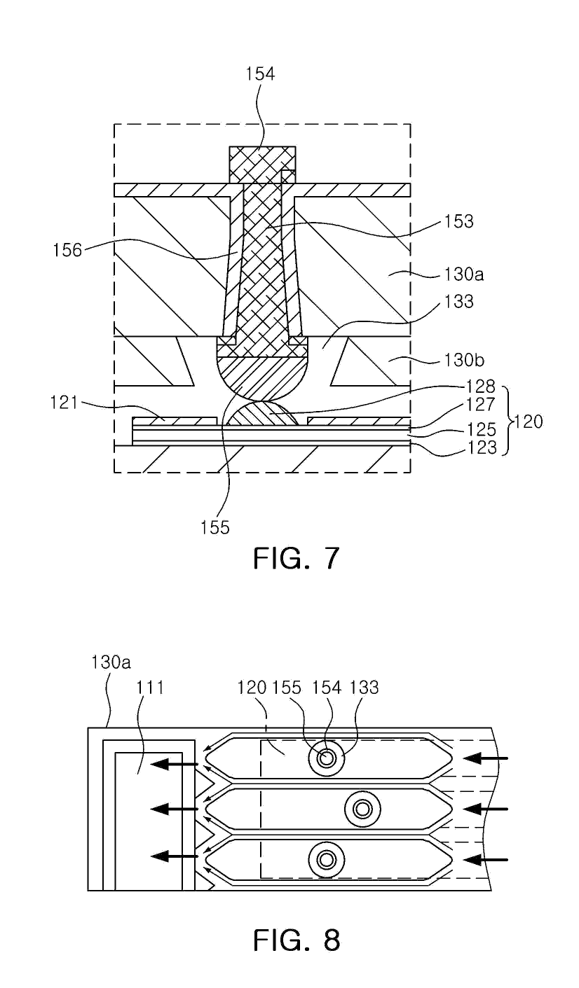

FIG. 5 is a schematic cutaway perspective view illustrating an inkjet head assembly according to another embodiment of the present invention. FIG. 6 is a schematic cross-sectional view illustrating the inkjet head assembly according to another embodiment of the present invention. FIG. 7 is a schematic plan view illustrating the inkjet head assembly according to another embodiment of the present invention.

Referring to FIGS. 5 through 7, the package unit 130 may include a flow path formation layer 130a in which an ink flow path for transferring ink supplied from an ink storage tank to the ink inlet 111 of the inkjet head plate 110 is formed, and an intermediate layer 130b for bonding the package unit 130 and the inkjet head plate 110. The package unit 130 may be formed of a silicon wafer, and in this case, the flow path formation layer 130a may be formed of a single crystalline silicon wafer and the intermediate layer 130b may be formed of a glass wafer. The flow path formation layer 130a and the intermediate layer 130b may be bonded through anodic bonding, glass frit bonding, or the like.

However, the configuration of the package unit 130 according to the embodiment of the present invention is merely illustrative, and the package unit 130 may be formed of a single silicon wafer, a plurality of silicon wafers, or an SOI wafer, and a design thereof may be variably modified, according to design requirements. The configurations of the flow path formation layer 130a and the intermediate layer 130b are also merely illustrative, and the intermediate layer 130b may be formed of a silicon wafer so as to be bonded with the flow path formation layer 130a through silicon direct bonding, and additionally, the designs of the flow path formation layer 130a and the intermediate layer 130b may be variably modified through polymer bonding, low-temperature silicon direct bonding using plasma, eutectic bonding, and the like.

The flow path formation layer 130a may include an ink inlet 151 through which ink supplied from the ink storage tank is introduced, an ink transfer unit 152 serving as a flow path for transferring the ink to the inkjet head plate 110, and a via 153 for an electrical wiring to apply a voltage to the piezoelectric actuator 120. The via 153 may be formed to penetrate upper and lower portions of the flow path formation layer 130a and may be disposed at one side of an upper portion of the piezoelectric actuator 120. Here, the ink inlet 151 may be formed at an opposite side of the via 153. Thus, in the mounting structure of the inkjet head assembly, the ink storage tank may be disposed at a central portion of an inkjet head assembly arrangement and the electrical wiring may be connected to an end portion of the inkjet head assembly, thus reducing a mounting area of the inkjet head assembly.

The ink inlet 151, the ink transfer unit 152, and the via 153 are formed in the silicon wafer through an etching process, and in particular, the via 153 may be formed to have a shape of a vertical hole having a certain diameter through dry etching or may be formed to have an inclined sidewall in such a manner that a diameter thereof is gradually increased toward a lower portion of the flow path formation layer 130a. Among dry etching methods, the via 153 may be formed through a reactive-ion etching (RIE) process, and in particular, a deep reactive-ion etching (DRIE) process. The via 153 may be filled with an electrical wiring metal to form an electrical connection unit 154.

The electrical connection unit 154 may be formed by plating the via 153 with a metal through electroplating, and the metal used herein may be at least any one of materials such as platinum (Pt), gold (Au), silver (Ag), nickel (Ni), titanium (Ti), copper (Cu), and the like. In order to ensure a stable electrical connection, the electrical connection unit 154 may be formed such that upper and lower ends thereof are larger than the circumference of the via 153, having a cross-section having an I-beam shape. However, the cross-section of the electrical connection unit 154 is not limited thereto and may have 1-like shape and T-like shape. Also, aside surface of the electrical connection unit 154 may be vertically formed so as to correspond to the shape of the via 153 or may be inclined.

The electrical connection unit 154 may include a connection member 155 formed in a lower end portion thereof, to connect the electrical connection unit 154 and the piezoelectric actuator 120. The connection member 155 may be made of a conductive material having a level of bonding force that will not cause an electrical short circuit. For example, the connection member 155 may be configured as a projection type connection member such as a solder ball, a solder bump, or the like, or an anisotropic conductive film (ACF), and in addition, various load application conductive type mediums may be used. In the present embodiment, it is assumed that a solder ball is used as the connection member 155. The connection member 155 may be connected to the connection unit 127a of the upper electrode 127 as described above.

In order to prevent a solder overflow phenomenon during solder reflow for bonding the solder ball to the piezoelectric actuator 120, a polymer film 121 may be coated on the upper surface of the piezoelectric actuator 120. Here, the polymer film 121 is formed on portions of the upper surface of the piezoelectric actuator 120, excluding the solder-bonded portion. The polymer film 121 may be formed by developing a material such as photoresist, or the like.

An oxide film 156 may be formed on an upper surface of the flow path formation layer 130a, a surface thereof in which the via 153 is formed, and a surface thereof in which the ink transfer unit 152 is formed. The oxide film 156 serves to prevent impurities contained in the silicon crystal of the flow path formation layer 130a formed of a silicon wafer from being diffused. The oxide film 156 may be formed such that silicon of the flow path formation layer 130a is oxidized to form an oxide film on the surface of the flow path formation layer 130a, and then the oxide film formed on a lower surface of the flow path formation layer 130a is removed through chemical-mechanical polishing (CMP), or the like.

The intermediate layer 130b may include a passage 131 allowing ink of the ink transfer unit 152 included in the flow path formation layer 130a to be supplied to the ink inlet of the inkjet head plate 110, an accommodation portion 132 accommodating the upper portion of the piezoelectric actuator 120, and a communication hole 133 allowing the accommodation portion 132 and the via 153 to be in communication with each other. The accommodation portion 132 of the piezoelectric actuator 120 may be formed as a recess depressed from a lower portion of the intermediate layer 130b toward an upper portion thereof, have a shape corresponding to the shape of the piezoelectric actuator 120, and have a depth equal to the sum of the thickness of the piezoelectric actuator 120 and an error. The accommodation portion 132 and the communication hole 133 may be formed by performing a sand blasting or an etching process on a glass wafer.

The package unit 130 formed by anodic-bonding the flow path formation layer 130a and the intermediate layer 130b is stacked on an upper surface of the inkjet head plate 110 and bonded thereto. In detail, a lower surface of the intermediate layer 130b and an upper surface of the inkjet head plate 110 are bonded through anodic bonding or glass frit bonding, and here, the connection member 155 of the electrical connection unit 154 is bonded to the upper surface of the piezoelectric actuator 120. In the present embodiment, bonding between the inkjet head plate 110 and the package unit 130 may be supported by bonded edges of the inkjet head plate 110 and the package unit 130.

In this manner, in the inkjet head assembly 100′ according to the present embodiment, the inkjet head plate 110 and the package unit 130 are bonded on a wafer level, a processing yield can be increased and manufacturing unit costs can be reduced, enhancing productivity.

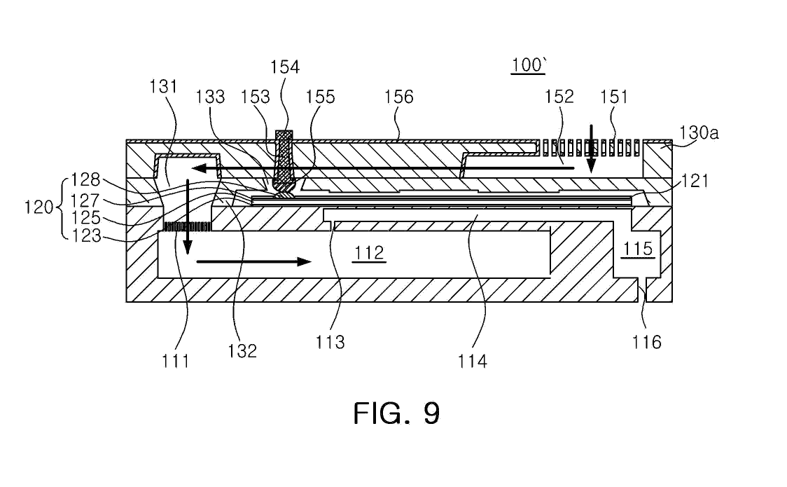

FIG. 8 is a schematic plan view illustrating an ink flow path of a package unit of the inkjet head assembly according to another embodiment of the present invention. FIG. 9 is a cross-sectional view showing the ink flow path of the inkjet head assembly according to another embodiment of the present invention.

Referring to FIGS. 8 and 9, ink introduced through the ink inlet 151 from an ink storage tank (not shown) is transferred in an arrow direction in the ink transfer unit 152. Here, ink may pass through a wall portion in which the via 153 for forming the electric connection unit 154 is formed and may be transferred from an end portion of the ink transfer unit 152 to the ink inlet 111 of the inkjet head plate 110 through the passage 131 of the intermediate layer 130b of the ink transfer unit 152.

Although a transfer movement path of ink introduced to the inkjet head plate 110 through the ink inlet 111 is not shown, it may be substantially the same as an ink transfer path of an inkjet head according to the related art. Namely, ink introduced through the ink inlet 111 may be transferred to the pressure chambers 114 through the plurality of restrictors 113 in the reservoir 112, and then, the ink within the pressure chambers 114 may be ejected to the outside from the nozzles 116 via the plurality of dampers 115 according to driving of the piezoelectric actuator 120.

An operation of the inkjet head assembly 100′ will hereinafter be described. Ink supplied through the inlet 151 from the ink storage tank (not shown) may be transferred in the arrow direction in FIGS. 8 and 9 so as to be supplied to each of the plurality of pressure chambers 114 of the inkjet head plate 110. In the state in which the pressure chambers 114 are filled with ink, when a voltage is applied to the piezoelectric actuator 120 through the electrical connection unit 154 connected to a flexible printed circuit board (not shown), the piezoelectric film is deformed, and accordingly, an upper portion of the inkjet head plate 110 serving as a vibration plate is bent downwardly. Since the upper portion of the inkjet head plate 110 is deformed to be bent, the volume of the pressure chambers 114 is reduced, and ink within the pressure chambers 114 is ejected to the outside through the nozzles 116 as the pressure within the pressure chambers 114 is increased.

Subsequently, when the voltage applied to the piezoelectric actuator 120 is cut off, the piezoelectric film is restored, and accordingly, the upper portion of the inkjet head plate 110 serving as a vibration plate is restored to increase the volume of the pressure chamber 114. Thus, ink is introduced into the pressure chambers 114 from the reservoir 112 due to the reduction in pressure within the pressure chambers 114 and surface tension according to meniscus of the ink formed within the nozzles 116.

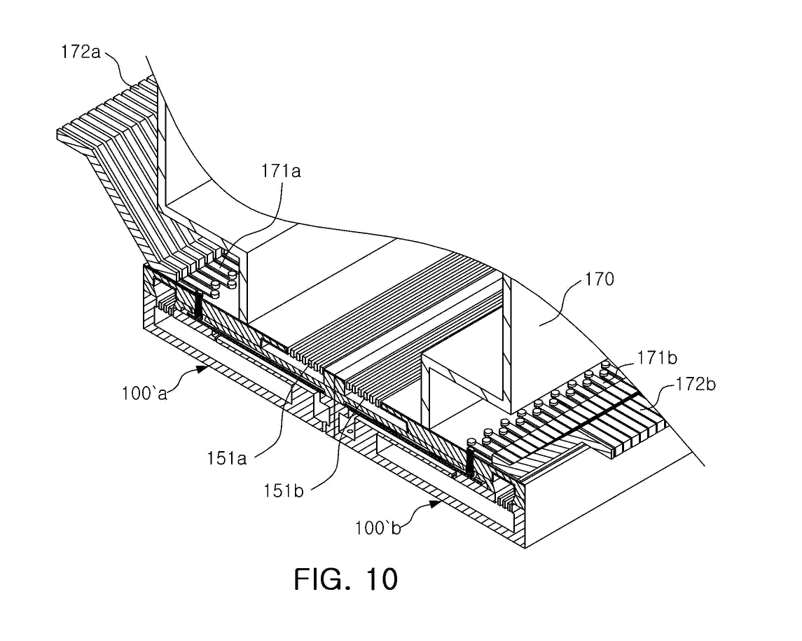

FIG. 10 is a schematic perspective view illustrating a mounting structure of the inkjet head assembly according to another embodiment of the present invention.

Referring to FIG. 10, a mounting structure of the inkjet head assembly 100′ includes a first inkjet head assembly 100′a and a second inkjet head assembly 100′b arranged to be symmetrical with relation to each other, an ink storage tank 170 disposed at the center of the upper portion of the first and second inkjet head assemblies 100′a and 100′ b, bonding units 171a and 171b formed on upper surfaces of the first and second inkjet head assemblies 100′a and 100′b and respectively connected to electrical connection units 154a and 154b and FPCBs 172a and 172b connected to the bonding units 171a and 171b in order to apply a voltage to the piezoelectric actuator of the first and second inkjet head assemblies 100′a and 100′b. The bonding units 171a and 171b may be made of an epoxy resin and, in particular, may be formed as anisotropic conductive films (ACFs).

In this manner, in the inkjet head assembly according to an embodiment of the present invention, since the electric wiring for applying a voltage to the piezoelectric actuator 120 is connected through the electrical connection unit 154 formed to be substantially perpendicular to the surface of the inkjet head assembly, whereby the area of the inkjet head assembly required for bonding the FPCB is reduced in comparison to the related art. Thus, the inkjet head assembly according to the present embodiment may have an area reduced by an amount equal to the area for a bonding of the FPCB and the area for a bonding of the ACF in the overall width of an inkjet head assembly according to the related art. In this case, since the ink storage tank is disposed in the central portion of an upper portion of a set of the inkjet head assemblies having a symmetrical structure in which nozzles are alternately formed, the mounting area of the inkjet head assembly can be significantly reduced. The reduction in the mounting area of the inkjet head assembly significantly reduces the overall width of the inkjet head assembly formed as a wafer level package, such that a larger number of inkjet head assemblies per wafer can be manufactured. Thus, the processing yield can be increased and the manufacturing unit costs can be reduced, enhancing productivity.

Hereinafter, a method of manufacturing an inkjet head assembly according to an embodiment of the present invention will be described briefly.

First, an ink flow path including a plurality of pressure chambers is formed in an inkjet head plate, and a lower electrode is formed on an upper portion of the inkjet head plate. Next, a piezoelectric body is formed through an application of a piezoelectric liquid in a paste state and a solidification thereof in such a manner that the piezoelectric body includes branch portions respectively provided to correspond to the plurality of pressure chambers and a large area portion connected to one end of each of the branch portions and integrally formed on an upper portion of the lower electrode.

Then, upper electrodes are separately formed to extend from the branch portions to the large area portion on an upper portion of the piezoelectric body, and connective electrode patterns are formed on upper portions of the upper electrodes provided on the large area portion, thus manufacturing an inkjet head assembly.

Of course, the ink storage tank may be installed in the foregoing state, and in order to operate the piezoelectric actuator, the connective electrode patterns provided on the upper portions of the upper electrodes as driving electrodes may be connected to a flexible printed circuit for a voltage application.

As set forth above, according to embodiments of the invention, the piezoelectric actuator and the inkjet head assembly are configured such that a portion thereof in which an external electrode is connected to a flexible printed circuit formed to be flat, whereby the external electrode and the flexible printed circuit can be accurately and firmly connected.

Also, in the piezoelectric actuator and the inkjet head assembly, since a driving electrode is not stripped even in case of wire bonding, product reliability can be secured.

The effect of the present invention can be variably implemented through the detailed description of the present invention.

While the present invention has been shown and described in connection with the embodiments, it will be apparent to those skilled in the art that modifications and variations can be made without departing from the spirit and scope of the invention as defined by the appended claims.

What is claimed is:

1. A piezoelectric actuator comprising:
upper and lower electrodes providing a driving voltage; and
a piezoelectric body provided between the upper and lower electrodes and providing driving force to ink within each of a plurality of pressure chambers provided in an inkjet head,
wherein the piezoelectric body includes branch portions separately provided on an upper portion of each of the plurality of pressure chambers and a large area portion connected to one end of each of the plurality of branch portions and integrally formed, and
a connective electrode pattern is provided on a portion of each of the upper electrodes corresponding to the large area portion.

2. The piezoelectric actuator of claim 1, wherein the upper electrodes are separately provided to extend from the branch portions to the large area portion.

3. The piezoelectric actuator of claim 2, wherein the upper electrodes includes connection portions provided on portions thereof positioned on an upper portion of the large area portion, and having a width greater than those of other portions for an electrical wiring to apply a voltage to the upper electrodes, and the connective electrode pattern is provided on each of the connection portions.

4. The piezoelectric actuator of claim 3, wherein the connection portions are provided in different positions in a length direction on a plurality of the upper electrodes.

5. The piezoelectric actuator of claim 3, wherein the connection portions are disposed in zigzags on a plurality of the upper electrodes.

6. An inkjet head assembly comprising:
an inkjet head plate in which an ink flow path is formed; and
a piezoelectric actuator formed to correspond to a plurality of pressure chambers within the inkjet head plate and providing driving force to eject ink from the pressure chambers to nozzles,
wherein the piezoelectric actuator includes:
upper and lower electrodes providing a driving voltage; and
a piezoelectric body formed between the upper and lower electrodes by solidifying a piezoelectric liquid and providing driving force to ink within each of the plurality of pressure chambers provided in an inkjet head,
wherein the piezoelectric body includes branch portions separately provided on an upper portion of each of the plurality of pressure chambers and a large area portion connected to one end of each of the plurality of branch portions and integrally formed, and
a connective electrode patterns is provided on an upper portion of each of the upper electrodes provided in the large area portion.

7. The inkjet head assembly of claim 6, wherein the upper electrodes are separately formed to extend from the branch portions to the large area portion.

8. The inkjet head assembly of claim 7, wherein the upper electrodes includes connection portions provided on portions thereof positioned on an upper portion of the large area portion, and having a width greater than those of other portions for an electrical wiring to apply a voltage to the upper electrodes, and the connective electrode pattern is provided on each of the connection portions.

9. The inkjet head assembly of claim 6, further comprising:
a package unit stacked on the inkjet head plate and having a flow path formed therein and allowing the ink introduced from an outside to be transferred to an inlet of the inkjet head plate; and
an electrical connection unit filled in a via formed to penetrate the package unit and electrically connected to the connective electrode pattern of the piezoelectric actuator.

10. The inkjet head assembly of claim 9, further comprising a connection member electrically connecting the electrical connection unit and the connective electrode pattern to each other.

11. The inkjet head assembly of claim 10, wherein the connection member is formed of a solder ball.

12. A method of manufacturing an inkjet head assembly, the method comprising:
forming an ink flow path including a plurality of pressure chambers in an inkjet head plate;
forming a lower electrode on an upper portion of the inkjet head plate;
forming a piezoelectric body through an application of a piezoelectric liquid in a paste state and a solidification thereof such that the piezoelectric body includes a plurality of branch portions respectively provided to correspond to the plurality of pressure chambers and a large area portion connected to one end of each of the plurality of branch portions and integrally formed, on an upper portion of the lower electrode;
separately forming upper electrodes to extend from the branch portions to the large area portion on an upper portion of the piezoelectric body; and
forming a connective electrode pattern on an upper portion of each of the upper electrodes provided on the large area portion.

13. The method of claim 12, wherein, in the forming of the upper electrodes, connection portions having a width greater than those of other portions are provided on portions of the upper electrodes positioned on an upper portion of the large area portion, for an electrical wiring to apply a voltage to the upper electrodes, and
the connective electrode pattern is provided on each of the connection portions.

14. The method of claim 13, wherein the connection portions are provided in different positions in a length direction on a plurality of the upper electrodes.
